(19) United States
(12) Patent Application Publication
(10) Pub. No.: US 2009/0134889 A1
(43) Pub. Date: May 28, 2009

(54) MOISTURE SENSOR APPARATUS AND METHOD

(76) Inventor: Metin Ata Gunsay, (US)

Correspondence Address: Metin Ata Gunsay, 136 E. Steep Mountain Dr., Draper, UT, 84020, US

(21) Appl. No.: 11/946,162

(22) Filed: Nov. 28, 2007

(51) Int. Cl. G01R 27/08

(52) U.S. Cl. 324/694

(57) ABSTRACT

A sensor to detect water moisture in soil or other water permeable materials having a capacitive probe or a transmission line acting as a probe, and electronic circuit. The sensor circuit includes a periodic signal generator to produce a carrier wave, which stimulates the transmission line, through a resistive or reactive coupling element. The resistive element also forms a voltage divider with the transmission line, wherein the output of the voltage divider, is demodulated with a simple AM demodulator, such as a peak detector. This demodulated signal is related to the dielectric constant, and thus the moisture of the material surrounding the transmission line.

### BACKGROUND OF THE INVENTION

1. Prior Art

The sensing and measuring of moisture in a medium is essential in many applications. For example, without limitation, automatic sprinkler systems can benefit from moisture sensors, by allowing them to conserve water when the soil is already sufficiently moist.

Several methods and devices for measuring water content or moisture of water permeable materials such as soil, and food products have traditionally been used. One well-known technique is to measure the dielectric constant of the medium under test. The dielectric constant of water is quite high at 80, whereas, other materials such as soil typically only have a dielectric constant of 4. Thus, changes to water content of a particular medium will have a proportional change in dielectric constant of the medium, which can be measured.

A particular problem with measuring and monitoring moisture content of materials, particularly soils, has been the expense, power consumption, and sophisticated nature of the equipment used. Traditional devices for measuring moisture content in soils have been relatively large, expensive, and have required relatively large amounts of electrical power, making large scale implementation in applications such as irrigation overly costly and cumbersome.

Various methods and apparatus exist for the detecting the presence of moisture in water permeable materials. For example many devices, such as shown in U.S. Pat. Nos. 5,148,125, 5,445,178, 5,424,649, 5,148,125, 6,981,405 and 6,060,889 determine the presence of moisture by measuring the phase delay of a transmission line buried in a material, by using the transmission line or capacitive probes as a circuit element of a oscillator. As the dielectric varies, the frequency of the oscillator varies. Methods such as these suffer from the disadvantage that in many cases for operation, a user must have access to both ends of the transmission line, and complex frequency demodulation circuitry is needed to extract the desired signal. In a similar method as shown in U.S. Pat. No. 7,126,352 a capacitive sensor is inserted into the bulk material, and the sensor acts as part of an RC multivibrator circuit, whose frequency varies according to the capacitance of the sensor. This approach requires active components, is not applicable to transmission lines, and requires an additional data recorder or frequency counter.

In one method, as shown in U.S. Pat. Nos. 6,204,670, 5,376,888, 5,212,453, 5,136,249 and 5,459,403 a transmission line is stimulated with a pulse and the reflected pulse propagation delay is measured. This method is undesirable, because the equipment needed to measure the delay, often a time domain reflectometer, is typically very expensive.

The transmission line base sensor as shown in U.S. Pat. No. 6,904,789 stimulates a transmission line with a fixed frequency; however, it is limited only to square waves. The invention describe herein has no such limitation and can be stimulated with any periodic signal, including but not limited to sine, square or triangular waves. If a non-square periodic signal is already available from another source in the system in which the sensor is embedded, this signal can be used to stimulate the transmission line, without the extra cost associated with adding an additional square wave oscillator.

The sensor of U.S. Pat. No. 6,904,789 also requires a phase detector composed of logic gates that require a separate supply voltage line. Since the sensor describe herein only requires passive components, such as diodes, resistors, and capacitors, and no active components, the sensor does not require a separate power supply line.

In view of the foregoing, there is a need to provide a moisture sensing apparatus, which is inexpensive to manufacture, easy to use, relatively accurate, and suitable for applications requiring multiple low cost sensors.

2. Objects and Advantages

Accordingly, several objects and advantages of the invention are:
(a) to reduce cost of the sensor electronics, by allowing any periodic waveform to be used to stimulate the sensor's transmission line;
(b) to reduce cost and size of the sensor electronics by use of a simple peak detector circuit;
(c) to reduce cost of the sensor, by allowing the use any sealed transmission line;
(d) to reduce the cost of multiple sensors, by allowing multiple sensors to share the same periodic frequency stimulus; and
(e) to flexibly allow the use of capacitive probes or transmission line based probes.
(f) to reduce the power consumption of the sensor by eliminating the need for active circuit components such as logic gates or op-amps.
(g) to simplify cabling requirements to remote water probe by removing the need for a separate power conductor, and by allowing coupling of a remote probe through a transmission line that is insensitive to the dielectric constant of the surrounding bulk material.

Still further objects and advantages will become apparent from a consideration of the ensuing description and drawings.

### SUMMARY

In accordance with the present invention a moisture sensor comprises a periodic signal generator, a coupled probe which is either capacitive or is a transmission line, and an AM demodulator.

### DRAWINGS

### Figures

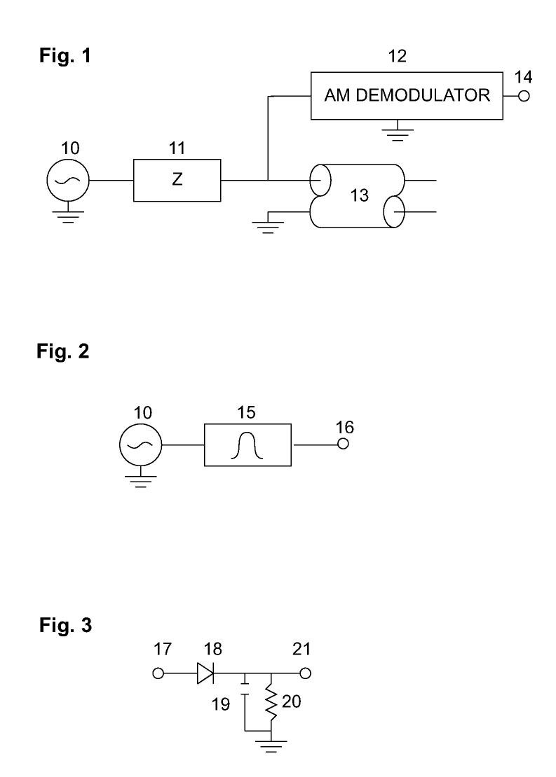

FIG. 1. is a block diagram of a water moisture sensor incorporating a transmission line probe according to the present invention.

FIG. 2. is a circuit diagram of a filtered periodic source.

FIG. 3. is a circuit diagram of a simple passive peak detector.

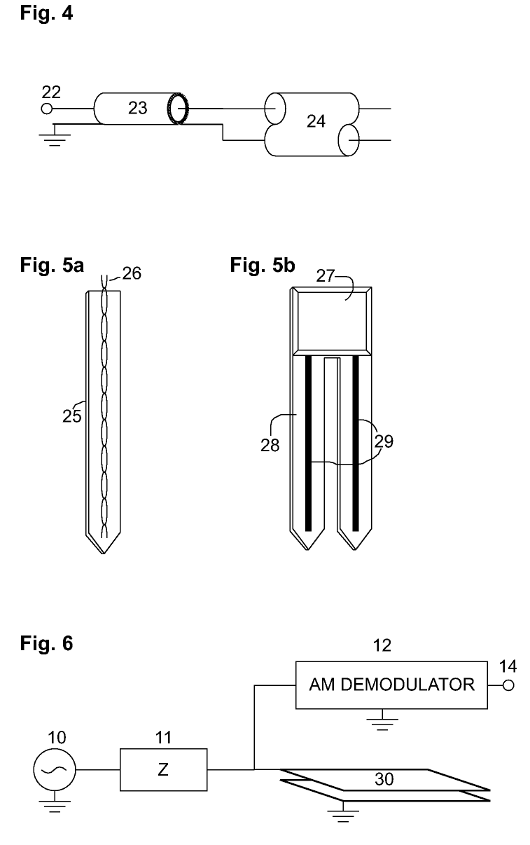

FIG. 4. is a block diagram showing a multi-segment transmission line.

FIG. 5a. is a perspective view of an embodiment of a transmission line probe, where a flexible transmission line is mounted on a rigid holder.

FIG. 5b. is a perspective view of an embodiment of a transmission line sensor, where the transmission line is embedded on the circuit board.

FIG. 6 is a block diagram of a water moisture sensor incorporating a capacitive probe according to the present invention.

### REFERENCE NUMERALS

| | |
|---|---|
| 10 | periodic voltage function generator |
| 11 | resistive or reactive element |
| 12 | AM demodulator |
| 13 | transmission line probe |
| 14 | output of sensor |
| 15 | filter circuit |
| 16 | output of filter circuit |
| 17 | input to peak detector |
| 18 | rectifier |
| 19 | capacitor |
| 20 | resistor |
| 21 | output of peak detector |
| 22 | input to transmission line probe |
| 23 | transmission line insensitive to surrounding dielectric |
| 24 | transmission line sensitive to surrounding dielectric |
| 25 | rigid holder |
| 26 | flexible transmission line |
| 27 | water tight over-molding |
| 28 | printed circuit board |
| 29 | conductive transmission line elements |
| 30 | capacitive probe |

### DETAILED DESCRIPTION

### FIGS. 1-3—Preferred Embodiment

A block diagram of the preferred embodiment is described in FIG. 1. A periodic function generator 10 provides a carrier frequency that is coupled to a transmission line probe 13 through a resistive or reactive element 11. The resistive or reactive element with the transmission line form a simple voltage divider, whose output voltage is related to the impedance of the transmission line. The magnitude of the carrier frequency will vary according to the dielectric constant of the transmission line probe, and correspondingly with the moisture of the material surrounding the transmission line. The output of this voltage divider is fed to a AM (amplitude modulation) demodulator 12 for the purpose of removing the carrier, and rendering a voltage to the sensor output 14 which is related to the moisture of the material surrounding the transmission line probe.

The signal generator 10 may produce any periodic carrier frequency of sufficient frequency to stimulate the transmission line. Many data electronic recording systems already have numerous oscillators or clock sources which can be used for this purpose. It is well known by those skilled in the art of electronics that all periodic waves can be band pass filtered or low pass filtered if the desired frequency is the fundamental frequency of the waveform, to produce a single frequency carrier. Thus, in the embodiment of FIG. 2, a filter circuit 15 is used to produce a single carrier frequency.

It is well known that the reactance of transmission lines alternates between negative and positive values every quarter wavelength of the carrier frequency, as the transmission line length increases. For example, a transmission line with an open circuit load, has a negative reactance, when the length of the line is less than a quarter wavelength of the carrier, and positive from above a quarter wavelength to below one half a wave length, and so on. The even quarter wavelength nodes are resonance points. Thus, in practice the carrier and the length of the transmission line are chosen for a desired reactance point. For example, the length of an open load transmission line could be chosen to be less than one quarter of a wavelength such that the reactance is negative. For applications where it is desired that the length of the transmission line be minimized, a higher carrier frequency should be used.

The resistive or reactive element 11 will typically be composed of a single resistor, but other reactive elements such as inductors or capacitors, or combinations thereof, can be used.

Many types of AM demodulator can be used, from specialized integrated circuits, to simple passive demodulators. One such passive demodulator is shown in FIG. 3. This is also known as a peak detector, and is comprised of and input 17, a rectifier 18, and a parallel connected capacitor 19 and resistor 20. The peak detector removes the carrier frequency and renders a waveform on the output 21, which tracks the envelope of the modulating frequency. Because passive components only need be used, no separate power supply is needed to power the electronic circuit, and the voltage supply only need be slightly greater than the forward voltage of the rectifying diode, allowing the circuit to use a very low voltage carrier. This circuit consumes very little power, making it ideal for remote battery operated applications.

The output of the sensor can be digitized using various methods, including the use of an analog to digital converter (ADC). This digitized signal can be passed to a microcontroller or computer system for further processing, such as averaging to remove noise and determination of the moisture content. The relationship between the voltage from the demodulator and the water moisture can be derived from a lookup table in the microcontroller that contains known relationship values for voltage and moisture content. It may alternatively be determined by the computer system by computing the reactance of the transmission line element given the known values of the carrier amplitude, and the impedance of the reactive or resistive element 11. Once the reactance of the probe is known the dielectric constant and correspondingly the water content of the bulk material may then be easily inferred.

Many types of transmission line based probes can be used as well. FIG. 4 shows a multi-segmented transmission line, wherein a transmission line that is insensitive to the dielectric constant of the medium through which it passes 23, such as coax, is used to merely couple the carrier frequency to the second transmission line which is sensitive to the carrier frequency 24. This is useful in applications where the sensor probe needs to be placed remotely away from the sensor electronics.

FIG. 5a shows another type of probe body that could be used. This probe is comprised of an inexpensive flexible transmission line such as a twisted pair 26, and a rigid elongated brace 25, whereby the transmission line may be more easily inserted into a bulk material.

FIG. 5b shows another type of probe body that could be used. It should be noted that this is just a specific example, and that many other circuit board shapes and geometries could be used. This probe is comprised of a single or multiple layer electronic circuit printed circuit board 28, with transmission lines as traces 29 on the circuit board, with the sensor's electronic circuit also on the circuit board (not shown) encapsulated in a water tight covering 27.

### Alternative Embodiment

### FIG. 6

A block diagram of an alternative embodiment is described in FIG. 6. A periodic function generator 10 provides a carrier frequency that is coupled to a capacitive probe 30 through a resistive or reactive element 11. The resistive or reactive element with the transmission line forms a simple voltage divider, whose output voltage is related to the impedance of the capacitor. The magnitude of the carrier frequency will vary according to the dielectric constant of the material in which the probe is inserted. The output of this voltage divider is fed to a AM (amplitude modulation) demodulator 12 for the purpose of removing the carrier, and rendering a voltage to the sensor output 14 which is related to the moisture of the material surrounding the transmission line probe.

As with the preferred embodiment discussed above, this alternative embodiment may similarly make use of a peak detector for the AM demodulator, and a filter circuit for the carrier signal.

### CONCLUSION, RAMIFICATIONS, AND SCOPE

Accordingly the reader will see that, the moisture sensor of this invention can be used with numerous types and configurations of probes, including transmission line based probes, and capacitive probes. In addition, because no active components such as oscillators, or logic gates are needed to process the signal from the probe element, the probe is very economical, consumes very little power, is compact, requires no supply voltage, and can be operated with a very low voltage carrier frequency.

While the above description contains many specificities, these should not be construed as limitations on the scope of the invention, but as exemplifications of the presently preferred embodiments thereof. Many other ramifications and variations are possible within the teachings of the invention. For example, the probe isn't necessarily limited to the measuring of water, but the apparatus and method could be used to measure the dielectric constant of any medium, thereby, determining the content of the said medium. In addition, a variety of the probe element types and geometries could be used.

Thus the scope of the invention should be determined by the appended claims and their legal equivalents, and not by the examples given.

What is claimed is:

1. A sensor for measuring water content of bulk materials, comprising:
a. a voltage signal generator which provides a carrier frequency,
b. a transmission line of one or more segments, where one input line is coupled to a circuit ground, and the other input line is coupled to the signal generator through
c. a resistive or reactive element,
d. an AM demodulator that is coupled to the reactive element providing an output voltage whereby the moisture content of the material may be determined.

2. A sensor for measuring water content of bulk materials according to claim 1 wherein the said AM demodulator circuit is comprised of a peak detector circuit, comprised of a diode whose anode is connected to the input of the peak detector, and whose cathode is coupled to the output of the peak detector as well as to a resistor in parallel with a capacitor whose other end is tied to the circuit's ground node.

3. A sensor for measuring water content of bulk materials according to claim 1 wherein the signal generated by the said voltage signal generator is pre-filtered reducing unwanted harmonics.

4. A sensor for measuring water content of bulk materials according to claim 1 wherein the said transmission line is composed of two or more different segments of transmission line, with the first segment being a transmission line which is insensitive to the dielectric constant of the medium through which it passes, and the second transmission line whose properties do change according to the dielectric constant of the medium through which it passes.

5. A sensor for measuring water content of bulk materials according to claim 1 wherein the said transmission line is comprised of traces on a circuit board, further with the circuit board comprising an electronic circuit.

6. A sensor for measuring water content of bulk materials according to claim 1 wherein the said transmission line is of a flexible material, that is reinforced with a rigid elongated brace.

7. A sensor for measuring water content of bulk materials, comprising:
a. a voltage signal generator which provides a carrier frequency,
b. a capacitive probe comprised of two plates separated enough to allow the bulk material to congregate, where one plate is coupled to circuit ground and the other is coupled to the signal generator through
c. a resistive or reactive element,
d. an AM demodulator that is coupled to the reactive element providing an output voltage whereby the moisture content of the material may be determined.

8. A sensor for measuring water content of bulk materials according to claim 7 wherein the said AM demodulator circuit is comprised of a peak detector circuit, comprised of a diode whose anode is connected to the input of the peak detector, and whose cathode is coupled to the output of the peak detector as well as to a resistor in parallel with a capacitor whose other end is tied to the circuit's ground node.

9. A sensor for measuring water content of bulk materials according to claim 7 wherein the signal generated by the said voltage signal generator is pre-filtered reducing unwanted harmonics.

10. A method of measuring water content of a bulk material, comprising the steps of:
a. providing a transmission line of one or more segments and embedding the transmission line into a bulk material;
b. providing a periodic voltage signal to the input of the transmission line through a reactive or resistive element;
c. providing an AM demodulator being coupled to the input of the transmission line with the demodulator providing an output signal related to the water content of the bulk material surrounding the transmission line;
d. determining the water content of the bulk material by the amplitude of the signal from the peak detector.

11. The method of claim 10, further comprising the steps of:
a. providing an analog to digital converter for the purpose of converting the voltage signal into a digitizing signal from the said peak detector of step (c);
b. averaging the said digital signal for the purpose of removing noise;
c. providing a computer or microcontroller, for the purpose of calculating the water content from the said digitized signal, via lookup table, calculation, or other numerical method.

12. The method of claim 10 further comprising the steps of: providing a temperature sensor input to the said computer or microcontroller, to allow the computer or microcontroller to incorporate ambient temperature into the water content calculations or lookup table, whereby a more accurate calculation of moisture content, which is temperature sensitive, can be calculated.
